(19) United States
(12) Patent Application Publication
(10) Pub. No.: US 2009/0078569 A1
(43) Pub. Date: Mar. 26, 2009

(54) INDUCTIVELY COUPLED PLASMA PROCESSING APPARATUS

(75) Inventors: Hirohisa Hirayanagi, Hachioji-shi (JP); Kiyotaka Sakamoto, Tama-shi (JP); Tomoaki Osada, Fuchu-shi (JP); Yoshimitsu Kodaira, Tama-shi (JP)

Correspondence Address: FITZPATRICK CELLA HARPER & SCINTO, 30 ROCKEFELLER PLAZA, NEW YORK, NY, 10112, US

(73) Assignee: CANON ANELVA CORPORATION, Kawasaki-shi (JP)

(21) Appl. No.: 12/211,023

(22) Filed: Sep. 15, 2008

(30) Foreign Application Priority Data
Sep. 25, 2007 (JP) 2007-246733

(51) Int. Cl. C23C 14/00

(52) U.S. Cl. 204/298.01

(57) ABSTRACT

An inductively coupled plasma processing apparatus according to the present invention prevents debris formed through a sputter etching operation from forming a film on an inner face of a side wall part 14 of a dielectric wall container 11 and a high-frequency power from being hindered to be supplied. All of straight lines which start from any one point on the outermost perimeter of an article to be processed 2 and pass through a plasma introduction port 12 form an intersecting point with the bottom part 13 of the dielectric wall container 11 on the inner face of the bottom part 13, in the inductively coupled plasma processing apparatus.

### CROSS-REFERENCES TO RELATED APPLICATIONS

This application also claims the benefit of priority from Japanese Patent Application No. 2007-246733 filed Sep. 25, 2007, the entire contents of which is incorporated herein by reference.

### BACKGROUND OF THE INVENTION

### Field of the Invention

The present invention relates to an inductively coupled plasma processing apparatus used for sputter etching processing or the like, for instance.

### RELATED BACKGROUND ART

### Related Arts

Presently, a physical sputter etching technique is used as one of etching processing techniques, which uses a metal material such as a refractory metal or a compound thereof such as an oxide thereof, which is easy to take selectivity for various materials, as a masking material. This sputter etching technique has been widely used for microprocessing for electrode parts of various electron devices and magnetic devices including an MRAM (magnetic random access memory).

In this process, a work object having a mask with a processing pattern formed on the surface to be processed is accommodated in the inner part of a gas-tight processing chamber. Subsequently, a processing gas (for instance, Ar) is supplied into the processing chamber, while the processing chamber is kept at a low pressure, and the processing gas is converted into plasma by a high-frequency magnetic field generated in the processing chamber. Then, ions contained in the plasma are accelerated by a bias voltage and are collided to the surface to be processed of the processing object, and thereby, a part of the surface to be processed, which is not masked, is scraped away (sputtering).

An inductively coupled plasma (ICP) processing apparatus, for instance, as is shown in Patent document 1, is known as one of apparatuses for performing processing as was described in the above. The ICP processing apparatus includes a vacuum vessel which forms a processing chamber for accommodating an article to be processed therein under a reduced pressure, and a dielectric wall container which forms a plasma chamber that communicates with the above described processing chamber through a plasma introduction port provided at a position opposing to the article to be processed in the processing chamber. The ICP processing apparatus also includes a coil electrode which is arranged in the outside of the side wall part of the dielectric wall container, and a high-frequency power source for plasma, which forms the plasma in the plasma chamber by applying a high-frequency power to the above described coil electrode.
[Patent document 1] Japanese Patent Application Laid-Open No. 2005-117010

### SUMMARY OF THE INVENTION

In a microprocessing process with the use of an ICP processing apparatus, a thin film of an electric conductor which is made from a metal (for instance, Pt, Ir or Ni) or a metallic oxide (for instance, iridium oxide or stannic oxide) is generally processed as an object.

When a large number of metallic processing objects are processed or processed for many hours, a metal which has been sputtered by plasma ions and scattered gradually deposits on an inner face of a side wall part of a dielectric wall container through a plasma introduction port, and forms a film thereon. When a metal film is thus formed on the inner face of the side wall part of the dielectric wall container, it becomes difficult for the dielectric wall container to supply a high-frequency power from a coil electrode to a plasma chamber. In addition, when the metal oxide is processed and deposits on the inner face of the side wall part of the dielectric wall container, the capacitance of the dielectric wall container changes, which causes a problem that a high-frequency power to be applied consequently varies.

The present invention has been designed to solve such a problem. An object of the present invention is to provide an ICP processing apparatus which supplies a high-frequency power to the inner face of the side wall part of the dielectric wall container without being hindered by a film formed on the inner face due to debris associated with sputter etching.

The present invention provides an ICP processing apparatus having a vacuum vessel which forms a processing chamber for accommodating an article to be processed therein under a reduced pressure, a dielectric wall container which forms a plasma chamber that communicates with the processing chamber through a plasma introduction port provided at a position opposing to the article to be processed in the processing chamber and is provided with a bottom part that opposes to the plasma introduction port and a side wall part that covers the circumference between the bottom part and the plasma introduction port, a coil electrode which is arranged in the outside of the side wall part of the dielectric wall container, and a high-frequency power source for plasma, which forms the plasma in the plasma chamber by applying a high-frequency power to the coil electrode, wherein all of straight lines which start from any one point on the outermost perimeter of the article to be processed and pass through the plasma introduction port form an intersecting point with the bottom part of the dielectric wall container on the inner face of the bottom part.

A structure such as the present invention can be formed, because plasma spreads uniformly in directions, while debris coming from the side of the article to be processed has directivity.

In an ICP processing apparatus according to the present invention, all of straight lines which start from any one point on the outermost perimeter of the article to be processed and pass through the plasma introduction port form an intersecting point with the bottom part of the dielectric wall container on the inner face of the bottom part. Accordingly, when debris formed through a sputter etching operation linearly flies, debris flying from the plasma introduction port into a plasma chamber collides against the inner face of the bottom part of the dielectric wall container and deposits thereon. Therefore, the ICP processing apparatus can greatly reduce the amount of the debris depositing on the inner face of the side wall part of the dielectric wall container, and can decrease the supply hindrance of a high-frequency power caused by a film formed on the inner face of the side wall part due to the deposition of the debris.

### BRIEF DESCRIPTION OF THE DRAWINGS

FIG. 1 is a schematic view illustrating a first example of an inductively coupled plasma processing apparatus according to the present invention.

FIG. 2 is a view for describing a dimension and a tilt angle in a main part of an inductively coupled plasma processing apparatus illustrated in FIG. 1.

FIG. 3 is a schematic view illustrating a second example of an inductively coupled plasma processing apparatus according to the present invention.

FIG. 4 is a view for describing a dimension and a tilt angle in a main part of an inductively coupled plasma processing apparatus illustrated in FIG. 3.

### DESCRIPTION OF THE PREFERRED EMBODIMENTS

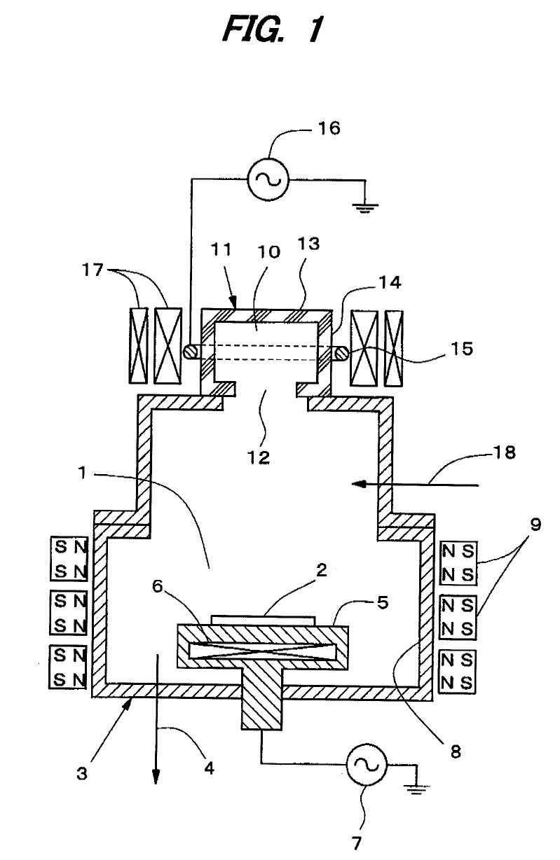

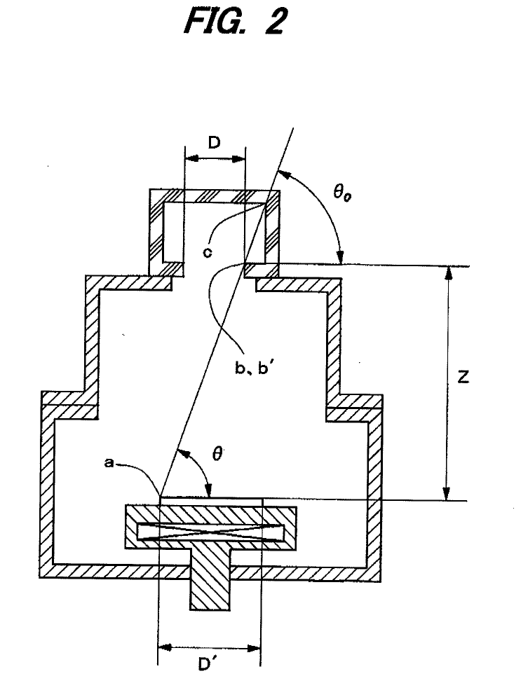

At first, a first example of an ICP processing apparatus according to the present invention will now be described below with reference to FIG. 1 and FIG. 2.

In FIG. 1, a reference numeral 1 is a processing chamber for accommodating a silicon substrate 2 of an article to be processed, for instance, which is formed of a vacuum container 3. The processing chamber 1 in the vacuum container 3 is connected with an exhaust system 4 so as to be capable of processing the silicon substrate 2 under a reduced pressure.

The processing chamber 1 has a holder 5 therein for mounting the silicon substrate 2 thereon. The holder 5 has a temperature control means 6 such as a heater for adjusting a temperature of the silicon substrate 2 provided therein, as needed. Furthermore, the holder 5 is connected with a high-frequency power source 7 for bias for applying a bias electric power.

A large number of magnets 9 for a side wall are provided in the outside of the side wall part 8 of the vacuum container 3. A large number of the magnets 9 for the side wall are arranged in a circumferential direction of the side wall part 8 of the vacuum container 3, and the magnetic poles on the side facing to the side wall part 8 are each different from those of adjacent magnets in a circumferential direction. The magnets 9 for the side wall form a cusped magnetic field continuously in a circumferential direction along the inner face of the side wall part 8 of the vacuum container 3, and prevent plasma from spreading to the inner face of the side wall part 8.

The vacuum container 3 is connected with a dielectric wall container 11 of which the inner part is a plasma chamber 10. The dielectric wall container 11 is arranged so as to communicate with the above described vacuum container 3 through a plasma introduction port 12 which is provided at a position opposing to a silicon substrate 2 that is an article to be processed in the vacuum container 3. In other words, the processing chamber 1 communicates with the plasma chamber 10 through the plasma introduction port 12, and the plasma formed in the plasma chamber 10 can be introduced to the processing chamber 1 through the plasma introduction port 12.

The dielectric wall container 11 is provided with a bottom part 13 opposing to the plasma introduction port 12 and a side wall part 14 for covering the circumference between the bottom part 13 and the plasma introduction port 12. At least the side wall part 14 is constituted by a dielectric substance such as a quartz glass. In the outside of the side wall part 14 constituted by the dielectric substance, a coil electrode 15 is arranged. The coil electrode 15 is connected with a high-frequency power source 16 for plasma, which apply a high-frequency power (source electric power) to the coil electrode 15 through a matching device (not shown) to make the plasma chamber 10 of the dielectric wall container 11 form the plasma. In the circumference of the side wall part 14, an electromagnet 17 is also provided so as to help the formation of plasma.

A reference numeral 18 denotes a gas introduction system for supplying a required processing gas (for instance, sputter etching gas) into the processing chamber 1 of the vacuum container 3. The coil electrode 15 shown in FIG. 1 is a one turn coil, but the present invention is not limited to the one turn coil.

In an ICP processing apparatus according to the present invention, all of straight lines which start from any one point on the outermost perimeter of a silicon substrate 2 and pass through the above described plasma introduction port 12 form an intersecting point with the bottom part 13 of the above described dielectric wall container 11 on the inner face of the bottom part 13. In other words, when the debris of Ni emitted from the silicon substrate coated with Ni or the like linearly flies along with sputter etching, the debris formed in the outermost perimeter of the silicon substrate 2 most easily reaches the inner face of the side wall part 14 of the dielectric wall container 11. However, an inductively coupled plasma processing apparatus according to the present invention is structured so that even the debris formed in the outermost perimeter of the silicon substrate 2 does not fly to the side wall part 14 but to the inner face of the bottom part 13, and the inner face of the bottom part 13 can receive the debris. For this reason, the ICP processing apparatus can prevent the debris from depositing on the inner face of the side wall part 14.

The reason will now be further described. Planar shapes of the silicon substrate 2, the plasma introduction port 12 and the inner face of the bottom part 13 of the dielectric wall container 11 form concentric circles with each other. In the first example shown in FIG. 1 as well, planar shapes of the silicon substrate 2, the plasma introduction port 12 and the inner face of the bottom part 13 of the dielectric wall container 11 form concentric circles with each other. In this case, when θ and θ₀ shown in FIG. 2 have a relationship of θ>θ₀, the above described debris can be prevented from depositing on the inner face of the side wall part 14. Here, θ is a tilt angle formed by a straight line that passes through one point (a) on the outermost perimeter of the silicon substrate 2 and one point (b) on a rim of the smallest bore of the plasma introduction port 12, which is most distant from the one point (a) and by the surface of the silicon substrate 2. θ₀ is a tilt angle of a straight line that passes through one point (c) on the inner intersection line on which the bottom part intersects with the side wall part of the dielectric wall container and one point (b′) (same point as point (b) in the figure) on the rim of the smallest bore of the plasma introduction port 12, which is nearest from the one point (c).

A state in FIG. 2 is a state of θ=θ₀. The above described θ₀ can be determined by the following expression (1), when a diameter of the silicon substrate 2 is determined as D′, the smallest bore (diameter) of the plasma introduction port 12 is determined as D, and a vertical distance between the rim in the plasma chamber 10 side of the smallest bore of the plasma introduction port 12 and the surface of the silicon substrate 2 is determined as Z.

θ₀=tan⁻[2Z/(D′+D)] (1)

Subsequently, a case is taken as an example, which employs an ICP processing apparatus shown in FIG. 1, uses Ar gas as a sputter etching gas, and etches a silicon substrate 2 that uses Ni as a masking material, and the operation state will now be described below.

At first, the inner part of a processing chamber 1 in a vacuum container 3 is exhausted by an exhaust system 4, a gate valve (not shown) is opened, and the silicon substrate 2 covered with Ni of the masking material is carried into the processing chamber 1. The silicon substrate 2 is held by a holder 5, and is kept at a predetermined temperature by a temperature control means 6.

Subsequently, a gas introduction system 18 is operated, and processing gas Ar is introduced into the processing chamber 1 in the vacuum container 3 at a predetermined flow rate. The introduced Ar gas 5 spreads into a plasma chamber 10 in a dielectric wall container 11 through the processing chamber 1 in the vacuum container 3. Here, a high-frequency power source is applied to a coil electrode 15 from a high-frequency power source 16 for plasma, and at the same time, an electromagnet 17 is operated to form plasma in the plasma chamber 10 in the dielectric wall container 11. At the same time, a high-frequency power source 7 for bias is operated to give self-bias voltage which is a voltage of a negative direct current to the silicon substrate 2, and to control ionic energy incident on the surface of an article to be processed 2, which comes from the plasma. In this way, the plasma spread from the plasma chamber 10 in the plasma dielectric wall container 11 into the processing chamber 1 in the vacuum container 3, reach the vicinity of the surface of the silicon substrate 2 and sputter-etch the surface of the silicon substrate 2. As this time, the debris of Ni or the like, which is formed through the sputter etching operation, results in colliding against the inner face of the bottom part 13 of the dielectric wall container 11 and depositing thereon, as was described above, and accordingly is prevented from depositing on the inner face of the side wall part 14.

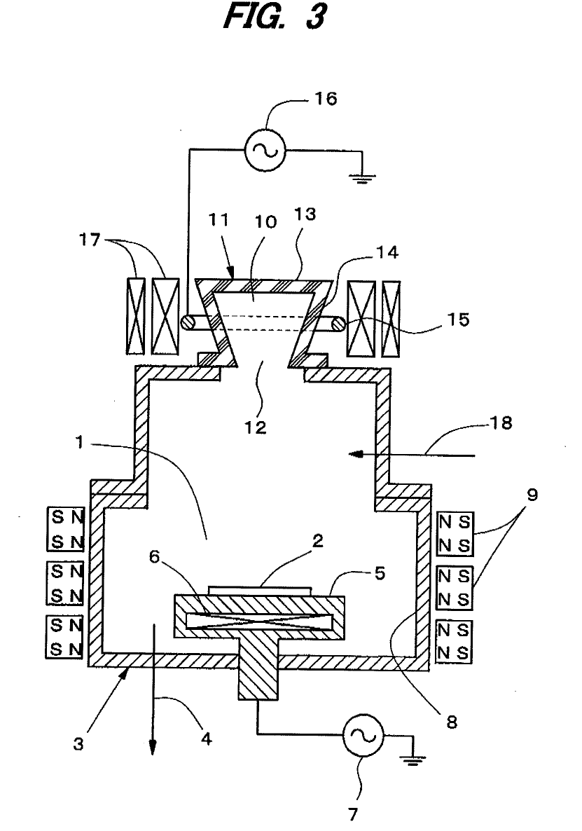

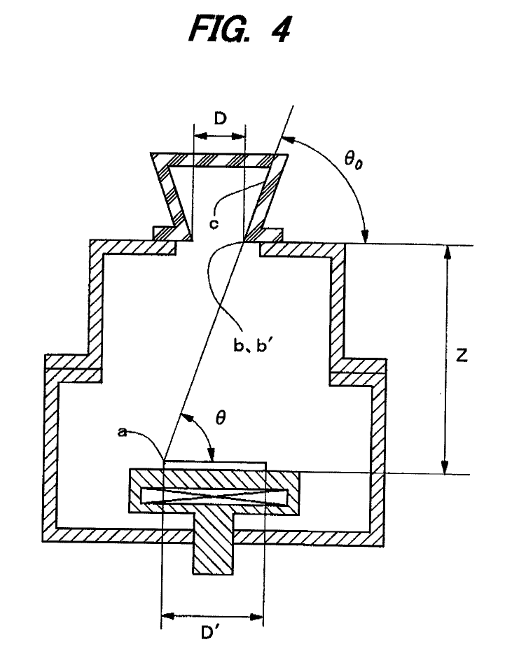

Next, a second example of an ICP processing apparatus according to the present invention will now be described below with reference to FIG. 3 and 4. In FIG. 3 and FIG. 4, the same reference numerals as in FIG. 1 and FIG. 2 denote the same member, site, dimension and angle as in FIG. 1 and FIG. 2.

The second example is basically similar to the first example, so that only dissimilar points will now be described below.

In the ICP processing apparatus according to the second example, a diameter of the inner face of the bottom part 13 of the dielectric wall container 11 is larger than the smallest bore of the plasma introduction port 12, and the side wall part 14 of the dielectric wall container 11 has such a circular truncated cone shape that the diameter gradually becomes smaller from the bottom part 13 toward the plasma introduction port 12. By doing this, a direction of the side wall part 18 of the dielectric wall container 11 can be set at a direction in which debris which has been formed on the silicon substrate 2 through a sputter etching operation and flies therefrom is harder to deposit on the side wall part 18. Accordingly, it is easier to prevent the debris which does not linearly fly from depositing on the side wall part 18. In the case of the illustrated second example, the smallest bore of the plasma introduction port 12 is constituted by a rim edge on the processing chamber 1 side of the side wall part, and θ₀ matches with a tilt angle of the side wall part 18.

The exemplary embodiment of the present invention was described above. However, the present invention is not limited to the embodiment, but can be changed to various modes within a technical scope which is grasped from the description of claims.

### EXAMPLE

Next, an article to be processed (silicon substrate) covered with a Ni mask was sputter-etched with the use of the ICP processing apparatus illustrated in FIG. 1. Processing conditions are as described below.
etching gas: Ar
flow rate of etching gas: 178.5 mg/min (100 sccm)
source electric power: 1,000 W
bias electric power: 300 W
pressure in vacuum container: 0.6 Pa
temperature of holder: 20° C.
etching period of time: 1 minute (per one piece)
etching rate: 30 nm/min

A thin film of Ni formed on the silicon substrate with the D′ of 200 mm was processed on the above described sputter etching conditions, and the result was evaluated by considering the number of substrates processed before the etching rate decreased by 10% as the substrate number of needing maintenance.

Here, the substrate number of needing maintenance was determined by a phenomenon in which the supplied high-frequency power was decreased because Ni having deposited on a dielectric wall container forms a thin film.

Table 1 is a measurement result showing a relationship between the tilt angle θ illustrated in FIG. 2 and the substrate number of needing maintenance (where five pieces are used as one unit). In the ICP processing apparatus used in the present example, the smallest bore D of the plasma introduction port is 100 mm, and a vertical distance Z between the rim on the plasma chamber side of the smallest bore part of the plasma introduction port and the surface of the article to be processed is 300 mm. In addition, θ₀ is 63.5 degrees, which is determined by the above described expression (1), because D′ is 200 mm as was described above.

TABLE 1

| | substrate number of needing |
|---|---|
| θ [°] | maintenance (piece) |
| 50 | 10 |
| 63.5 (=θ₀) | 105 |
| 77 | 2015 |

From Table 1, it was confirmed that the substrate number of needing maintenance increased when θ was made larger than θ₀, because Ni easily deposited on the bottom part of the dielectric wall container.

When the value Z was fixed, the value of θ could be increased by decreasing the smallest bore D of the plasma introduction port. Then, a Ni film hardly deposited on the side wall part of the dielectric wall container, which could increase the substrate number of needing maintenance.

Here, when the substrate has φ of 200 mm, the smallest bore D of the plasma introduction port can be changed in the range of 40 mm≦D≦180 mm, and the vertical distance Z between the rim on the plasma chamber side of the smallest bore of the plasma introduction port and the surface of the article to be processed can be changed in the range of 100 mm≦Z≦500 mm.

In addition, when the substrate has φ of 300 mm, the smallest bore D of the plasma introduction port can be changed in the range of 60 mm≦D≦270 mm, and the vertical distance Z between the rim on the plasma chamber side of the smallest bore of the plasma introduction port and the surface of the article to be processed can be changed in the range of 100 mm≦Z≦600 mm.

What is claimed is:

1. An inductively coupled plasma processing apparatus comprising a vacuum vessel which forms a processing chamber for accommodating an article to be processed therein under a reduced pressure; a dielectric wall container which forms a plasma chamber that communicates with the processing chamber through a plasma introduction port provided at a position opposing to the article to be processed in the processing chamber and is provided with a bottom part that opposes to the plasma introduction port and a side wall part that covers the circumference between the bottom part and the plasma introduction port; a coil electrode which is arranged in the outside of the side wall part of the dielectric wall container; and a high-frequency power source for plasma, which forms the plasma in the plasma chamber by applying a high-frequency power to the coil electrode,
wherein all of straight lines, which start from any one point on the outermost perimeter of the article to be processed that has been mounted in the processing chamber and pass through the plasma introduction port, form an intersecting point with the bottom part of the dielectric wall container on the inner face of the bottom part.

2. The inductively coupled plasma processing apparatus according to claim 1, wherein when a tilt angle which is formed by a straight line that passes through the one point on the outermost perimeter of the article to be processed and one point on a rim at the smallest bore portion of the plasma introduction port, which is positioned in the most distant part from the one point, and by the surface of the article to be processed is determined as θ, and a tilt angle of a straight line that passes through one point on an inner intersection line formed by the bottom part and the side wall part of the dielectric wall container and one point on a rim at the smallest bore part of the plasma introduction port, which is positioned in the nearest part from the one point, is determined as θ₀, θ>θ₀.

3. The inductively coupled plasma processing apparatus according to claim 1 or 2, wherein a diameter in the inner face of the bottom part of the dielectric wall container is larger than the smallest bore of the plasma introduction port, and the side wall part of the dielectric wall container forms a circular truncated cone shape of which the diameter gradually becomes smaller from the bottom part toward the plasma introduction port.

4. An inductively coupled plasma processing apparatus comprising:
a plasma-forming chamber that has a magnetic-field-forming part of which the periphery is surrounded by a coil electrode and forms plasma therein by applying a high-frequency power to the coil electrode, and
a processing chamber which communicates with the plasma-forming chamber and accommodates an article to be processed therein at a position that intersects with a pivot of the coil electrode, wherein
all of straight lines that start from any one point on the article to be processed which has been mounted in the processing chamber, pass through a communicating part of the processing chamber with the plasma-forming chamber and reach the plasma-forming chamber have intersecting points on the plasma-forming chamber in a closer side to the pivot than the magnetic-field-forming part of the plasma-forming chamber.

5. An inductively coupled plasma processing apparatus comprising:
a plasma-forming chamber that has a magnetic-field-forming part of which the periphery is surrounded by a coil electrode and forms plasma therein by applying a high-frequency power to the coil electrode; and
a processing chamber which communicates with the plasma-forming chamber and accommodates an article to be processed therein at a position that intersects with a pivot of the coil electrode, wherein
the plasma-forming chamber makes its communicating part with the processing chamber protrude to a closer side to the pivot than the magnetic-field-forming part.

6. An inductively coupled plasma processing apparatus comprising:
a plasma-forming chamber that has a magnetic-field-forming part of which the periphery is surrounded by a coil electrode and forms plasma therein by applying a high-frequency power to the coil electrode;
a processing chamber which communicates with the plasma-forming chamber and accommodates an article to be processed therein at a position that intersects with a pivot of the coil electrode; and
a protruding member which is located in between the plasma-forming chamber and the processing chamber, has an opening part in a closer side to the pivot than the magnetic-field-forming part and prevents debris from flying from the article to be processed to the magnetic-field-forming part.

7. A dielectric container to be used in an inductively coupled plasma processing apparatus, comprising:
a magnetic-field-forming part of which the periphery is surrounded by a coil electrode; and
an opening part through which plasma can be discharged,
wherein the opening part has a tapered side wall formed so that the opening part can be positioned in a closer side to the pivot than the magnetic-field-forming part.
